(19) United States
(12) Patent Application Publication
(10) Pub. No.: US 2025/0021010 A1
(43) Pub. Date: Jan. 16, 2025

(54) DEVICE AND METHOD FOR ALIGNING TWO COMPONENTS

(71) Applicant: Carl Zeiss SMT GmbH, Oberkochen (DE)

(72) Inventors: Eduard Schweigert, Syrgenstein (DE); Uwe Wittig, Oberkochen (DE)

(21) Appl. No.: 18/901,513

(22) Filed: Sep. 30, 2024

Related U.S. Application Data
(63) Continuation of application No. PCT/EP2023/058458, filed on Mar. 31, 2023.

(30) Foreign Application Priority Data
Apr. 6, 2022 (DE) 102022203393.0
Aug. 24, 2022 (DE) 102022208738.0

(51) Int. Cl. G03F 7/00

(52) U.S. Cl. CPC G03F 7/70258; G03F 7/70833; G03F 7/7095

(57) ABSTRACT

Disclosed is a method for aligning two components (31, 33) of a projection exposure apparatus (1, 101) for semiconductor lithography, comprising:
inserting at least one mandrel (30, 50) of a first component (33) into a recess (94) in a second component (31) in the z-direction,
preloading the mandrel (30, 50) perpendicular to the z-direction to a predetermined torque for pre-positioning the two components (31,33) in relation to each other in the x-y plane,
positioning the two components (31, 33) in the z-direction until they are in contact with a contact force F_{A},
bracing the mandrel (30, 50) with the recess (94) with maximum torque,
positioning the two components in the z-direction until the first component (31) rests on the second component (33) with maximum weight force Fₘₐₓ.

Also disclosed is device for aligning the two components (31, 33) comprises the mandrel.

### CROSS-REFERENCE TO RELATED APPLICATIONS

The present application claims the priority of the German patent application DE 10 2022 203 393.0 of Apr. 6, 2022 and DE 10 2022 208 738.0 of Aug. 24, 2022, and also International Application No. PCT/EP2023/058458 filed on Mar. 31, 2023, the content of which are fully incorporated herein by reference.

### TECHNICAL FIELD

This disclosure relates to a device and a method for aligning components, in particular components of a projection exposure apparatus for semiconductor lithography.

### BACKGROUND

Projection exposure apparatuses are subject to extremely high demands in terms of the imaging accuracy, which among other things largely depends on the positioning of the optical elements and thus the components of the projection exposure apparatus.

The achieved accuracy of the positioning of the optical elements is made up of a pre-alignment achieved during the assembly of the optical elements and a subsequent positioning of the optical elements by manipulators. The accuracy that can be achieved by the manipulators also depends, among other things, on a maximum required total travel path, which is also determined by the accuracies achieved during the pre-alignment of the components. The greater the required travel path of the manipulators, the lower is the resolution required for positioning accuracy. Demands placed on projection exposure apparatuses regarding the positioning accuracy of the optical elements, which increase from generation to generation, therefore also lead to ever higher demands placed on the alignment of the optical elements in relation to a global reference in the assembly.

In addition, the increasingly modular design of projection exposure apparatuses, which has the aim of being able to simply exchange defective modules at the customer's site or to replace them with further developed and improved modules, leads to a further increase in the demands regarding the accuracy of the alignment of the optical elements or components during assembly. The accuracies achieved during an exchange at the customer's site are worse than during initial assembly due to a lack of or limited availability of measurement means in the devices and methods used from the prior art.

Furthermore, the demand for a plug-and-play process at the customer's site, i.e. any replacement of components without pairing modules as is frequently used in the prior art, leads to increased demands regarding the accuracy of the alignment of the components with one another. These increased demands can increasingly no longer be met by the devices and methods currently used in the prior art.

### SUMMARY

In certain aspects, this disclosure is directed to specify a device and a method with which components can be aligned with the required accuracy.

In certain aspects, disclosed is a method for aligning two components of a projection exposure apparatus for semiconductor lithography that comprises the following method steps:
inserting at least one mandrel of a first component into a recess in a second component in the z-direction;
preloading the mandrel perpendicular to the z-direction to a predetermined torque in order to pre-position the two components in relation to each other in the x-y plane;
positioning the two components in the z-direction until they are in contact with a contact force F_{A};
bracing the mandrel with the recess with maximum torque;
positioning the two components in the z-direction until one component rests on the second component with maximum weight force Fₘₐₓ.

The two components can be designed, for example, as an optical module and a frame of a projection exposure apparatus for semiconductor lithography, wherein in one embodiment, the optical module is mounted on the frame and placed on it. The number of mandrels depends on the design of the mandrels, but is expediently selected in such a way that the alignment of the components relative to one another is determined statically. The interactive procedure when positioning the two components in an x-y plane on the one hand and in a z-direction perpendicular thereto on the other hand has the advantage that a possible generation of particles can be minimized.

Due to the mandrels arranged in the recesses, particles generated at the mandrel or in the recess are initially generated on the rear side of an optical effective surface arranged on the optical component, i.e., the surface exposed to radiation for the purpose of imaging the structures. As a result, the path to the optical effective surface to be overcome by the particles is very large. Furthermore, the relative movement between the components that are in contact during fine positioning can be minimized by the pre-positioning effected by pre-loading of the mandrel. In addition, the particles generated during pre-positioning and fine-positioning are trapped in the contact area between the components during the assembly process.

In particular, the frame can be braced with a contact force of less than 1000 N, preferably less than 100 N and particularly preferably less than 10 N, between the two components. As already explained further above, the risk of particle generation is dependent on the contact force and the distance travelled by the surfaces in contact during fine positioning, and so a lower contact force is advantageous during fine positioning.

In a further embodiment of the method, the at least one mandrel can be loosened once at the end of the method and tightened again to the maximum extent. This has the advantage that tension that is caused by and frozen during the complete loading of the weight of the optical module when it is lowered onto the frame in the optical module can be relaxed. As a result, no parasitic deformations can occur on the optical effective surface already explained above.

In another aspect, disclosed is a device for aligning two components of a projection exposure apparatus for semiconductor lithography is characterized in that the device comprises a mandrel. A mandrel is a clamping means known from the field of machine tools, which effects a radial expansion of the mandrel through an axial movement or feed in the mandrel. The mandrel typically comprises a cone with a clamping sleeve that is arranged thereon and corresponds to the outer geometry of the cone. By moving the cone relative to the clamping sleeve, the latter is pushed onto the cone and expands radially because of it. In the case of a manually actuated mandrel, the relative movement between the cone and the clamping sleeve is achieved by hand using a clamping nut or clamping screw. Alternatively, the mandrel can also be actuated hydraulically, electrically, or pneumatically via a clamping cylinder. In the case of this device, the radial expansion of the mandrel does not act to brace the two components, but rather as a means for aligning the two components with one another.

In particular, the mandrel can be permanently connected to one of the two components. A main body of the mandrel can be aligned with a local or global reference on one of the components.

Furthermore, the other component can have a recess that corresponds to the outer diameter of the mandrel. The recess can be designed as a hollow cylinder in the form of a drilled hole or as another arbitrary inner contour.

In addition, the mandrel can be designed in such a way that it can assume a released and a braced state. In the released state, the mandrel is first inserted into the recess, hereinafter referred to as drilled hole, of the other component. The clearance between the released mandrel and the drilled hole can be chosen such that joining is easily possible and the increased risk of work hardening during joining, in particular in a vacuum environment, such as in an EUV projection exposure apparatus, can be avoided.

In particular, the joint clearance between the drilled hole and the mandrel in a released state can be greater than or equal to 30 μm. After joining, the mandrel can be brought into the braced state, which reduces the clearance between the mandrel and the drilled hole. Depending on the position of the components relative to one another, when the mandrel is braced, there may be a relative movement between the components, i.e., the components may align with one another. The bracing of the mandrel can advantageously increase the accuracy of the alignment of the two components relative to each other. In the event of a manually actuated mandrel, the mandrel is actuated by hand using a clamping nut or clamping screw. Alternatively, the mandrel can also be actuated hydraulically, electrically, or pneumatically via a clamping cylinder.

In the braced state, the joint clearance between the drilled hole and the mandrel can be less than 30 μm, preferably less than 15 μm, and particularly preferably less than 5 μm.

In a further embodiment, a clamping element, for example a clamping screw or a clamping nut of the mandrel, can be connected to a clamping sleeve or a main body in such a way that only axial forces can be transmitted. This decoupling of the force transmission can be realized, for example, by a ball bearing arranged between an intermediate piece and the clamping sleeve.

Furthermore, the clamping sleeve and/or the main body can be coated with a friction-reducing layer. The coating can be, for example, a ceramic layer, such as a what is known as DLC (diamond like carbon) coating, which can lead to less generation of particles. This can be advantageous for the use of the mandrel in a vacuum environment or an environment with high requirements relating to freedom from particles, such as in a clean room.

In a further embodiment of the device, the outer contour of the clamping sleeve or the inner contour of the corresponding recess can have a rounded geometry. This can have the advantage that, for example, only a line contact occurs between the drilled hole and the outer contour of the clamping sleeve, i.e., no overdetermination and thus jamming can occur.

Furthermore, the device can comprise a weight compensation unit for one of the components. The weight compensation unit reduces the frictional force between the components and thus the force that the mandrel has to apply to align the two components with one another.

In particular, the alignment can thus be carried out with a contact force of less than 1000 N, preferably less than 100 N, and particularly preferably less than 10 N. The contact force is here the normal force, acting on the contact surface, between the clamping sleeve and the main body, which directly determines the frictional force. A reduction in the frictional force can advantageously lead to less particle generation. Furthermore, the weight compensation unit of the various components can be aligned in such a way that, regardless of the components' own weight, the force for aligning the components is comparable. As a result, the same mandrel could be used to align all components, achieving savings in development and production costs.

In a further embodiment, the device may include an indicator to indicate successful alignment. This indicator can communicate, using a visual, acoustic or tactile signal, that the alignment of the two components relative to one another has been reliably achieved within the predetermined accuracies. For example, a control pin can be arranged in the mandrel in such a way that the control pin is flush with an outer surface of the mandrel or extends beyond it when the predetermined bracing and thus the alignment accuracy have been achieved.

Furthermore, the mandrel can have a predetermined maximum travel, which can be implemented, for example, via a fixed stop for the clamping screw or the clamping nut.

In particular, the predetermined maximum travel can be settable. This can be an advantage if the tolerances for the travel cannot be observed by simple assembly due to the tolerance chain of the component parts used. The setting can be implemented, for example, using a shim that can be adapted in terms of thickness as required. Alternatively, the stop can also be adapted or reworked after measuring the travel.

In a further embodiment, the mandrel can have a revolving ball bearing. The ball bearing filled with balls connects an intermediate piece of the mandrel to the clamping sleeve and can only transmit axial forces. The clamping sleeve no longer rotates when being braced owing to the balls. The resulting greatly reduced relative movement of the clamping sleeve on the main body advantageously reduces the formation of particles. The particles can be held back in the mandrel by a seal encompassing the gap between the clamping sleeve and the main body and also the partially slotted clamping sleeve. As a result, the mandrel gives off almost no particles to the outside and can be considered suitable for clean rooms and vacuum applications.

In particular, the clamping sleeve can have a stiff and an elastic partial region. A first half of the ball bearing can be arranged in the stiff partial region, and because of it, this half does not change its diameter even when the mandrel is braced. The elastic region can be formed, for example, by decoupling cuts in such a way that an extensive contact surface between the clamping sleeve and a cone on the main body is ensured during bracing.

Furthermore, the clamping sleeve can have a monolithic structure.

In a further embodiment, a thread effecting the travel can be arranged internally. Within the meaning of the application, internal is to be understood as meaning that the thread is arranged within a volume which is almost completely closed off from the environment.

In particular, a volume surrounding the thread can be sealed off from the outside by at least one seal to avoid particle contamination. This embodiment can be suitable in particular for use in areas with high requirements in terms of freedom from particles, as is required, for example, in clean rooms and in many vacuum environments.

Other aspects, embodiments, and advantages follow.

### DESCRIPTION OF DRAWINGS

Exemplary embodiments and variants will be explained in more detail below with reference to the drawing, in which

FIG. 1 schematically shows a meridional section of a projection exposure apparatus for EUV projection lithography,

FIG. 2 schematically shows a meridional section of a projection exposure apparatus for DUV projection lithography,

FIG. 3 shows a first embodiment schematically,

FIG. 4 shows a further embodiment,

FIG. 5 shows a detail of the embodiment, and

FIGS. 6A-6F show a possible method.

### DETAILED DESCRIPTION

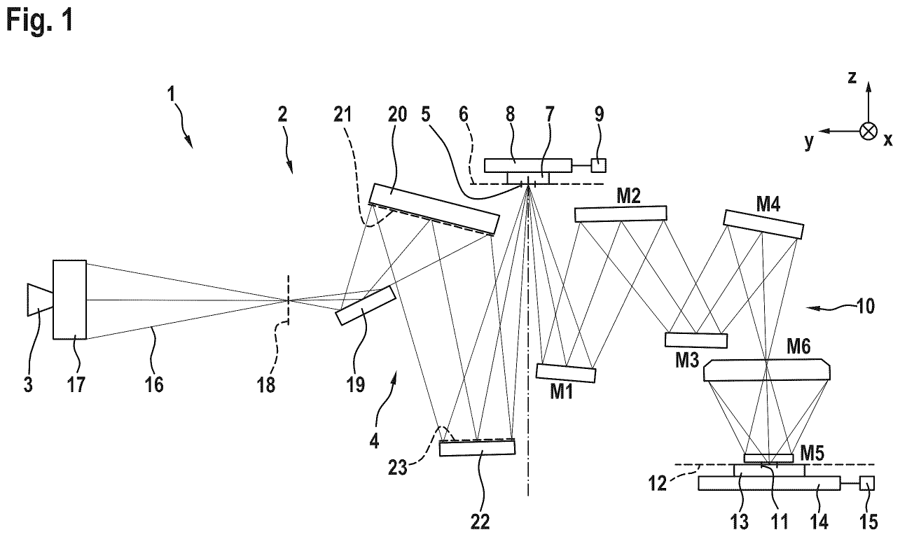

The essential integral parts of a microlithographic projection exposure apparatus 1 are described in exemplary fashion below initially with reference to FIG. 1. The description of the fundamental construction of the projection exposure apparatus 1 and the integral parts thereof is understood here to be non-limiting.

One embodiment of an illumination system 2 of the projection exposure apparatus 1 has, in addition to a radiation source 3, an illumination optical unit 4 for illuminating an object field 5 in an object plane 6. In an alternative embodiment, the light source 3 may also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable by way of a reticle displacement drive 9 in particular in a scanning direction.

A Cartesian xyz-coordinate system is shown in FIG. 1 for explanation purposes. The x-direction runs perpendicular to the plane of the drawing into the latter. The y-direction runs horizontally, and the z-direction runs vertically. The scanning direction runs longitudinally with respect to the y-direction in FIG. 1. The z-direction runs perpendicular to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15 in particular longitudinally with respect to the y-direction. The displacement, firstly, of the reticle 7 by way of the reticle displacement drive 9 and, secondly, of the wafer 13 by way of the wafer displacement drive 15 may be implemented so as to be mutually synchronized.

The radiation source 3 is an EUV radiation source. The radiation source 3 emits, in particular, EUV radiation 16, which is also referred to below as used radiation, illumination radiation or illumination light. In particular, the used radiation has a wavelength in the range of between 5 nm and 30 nm. The radiation source 3 can be a plasma source, for example an LPP (laser produced plasma) source or a GDPP (gas discharge produced plasma) source. It may also be a synchrotron-based radiation source. The radiation source 3 may be a free electron laser (FEL).

The illumination radiation 16 emerging from the radiation source 3 is focused by a collector 17. The collector 17 can be a collector with one or with a plurality of ellipsoidal and/or hyperboloidal reflection surfaces. The illumination radiation 16 can be incident on the at least one reflection surface of the collector 17 with grazing incidence (GI), that is to say at angles of incidence of greater than 45° relative to the direction of the normal to the mirror surface, or with normal incidence (NI), that is to say at angles of incidence of less than 45°. The collector 17 can be structured and/or coated firstly for optimizing its reflectivity for the used radiation and secondly for suppressing extraneous light.

Downstream of the collector 17, the illumination radiation 16 propagates through an intermediate focus in an intermediate focal plane 18. The intermediate focal plane 18 can represent a separation between a radiation source module, having the radiation source 3 and the collector 17, and the illumination optical unit 4.

The illumination optical unit 4 comprises a deflection mirror 19 and, arranged downstream thereof in the beam path, a first facet mirror 20. The deflection mirror 19 may be a plane deflection mirror or, alternatively, a mirror with a beam-influencing effect going beyond a pure deflection effect. Alternatively or in addition, the deflection mirror 19 may be embodied in the form of a spectral filter that separates a used light wavelength of the illumination radiation 16 from extraneous light of a wavelength deviating therefrom. If the first facet mirror 20 is arranged in a plane of the illumination optical unit 4 that is optically conjugate to the object plane 6 as a field plane, it is also referred to as a field facet mirror. The first facet mirror 20 comprises a multiplicity of individual first facets 21, which are also referred to below as field facets. FIG. 1 depicts only some of said facets 21 by way of example.

The first facets 21 can be embodied in the form of macroscopic facets, in particular in the form of rectangular facets or in the form of facets with an arcuate peripheral contour or a peripheral contour of part of a circle. The first facets 21 can be embodied as plane facets or, alternatively, as convexly or concavely curved facets.

As known for example from DE 10 2008 009 600 A1, the first facets 21 themselves can also be composed in each case of a multiplicity of individual mirrors, in particular a multiplicity of micromirrors. In particular, the first facet mirror 20 can be embodied as a microelectromechanical system (MEMS system). For details, reference is made to DE 10 2008 009 600 A1.

The illumination radiation 16 travels horizontally, that is to say longitudinally with respect to the y-direction, between the collector 17 and the deflection mirror 19.

In the beam path of the illumination optical unit 4, a second facet mirror 22 is arranged downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or hexagonal boundary, or may alternatively be facets composed of micromirrors. In this regard, reference is likewise made to DE 10 2008 009 600 A1.

The second facets 23 may have plane reflection surfaces or alternatively convexly or concavely curved reflection surfaces.

The illumination optical unit 4 consequently forms a doubly faceted system. This fundamental principle is also referred to as a fly's eye condenser (fly's eye integrator).

It can be advantageous to arrange the second facet mirror 22 not exactly in a plane that is optically conjugate to a pupil plane of the projection optical unit 10. In particular, the pupil facet mirror 22 can be arranged so as to be tilted relative to a pupil plane of the projection optical unit 10, as is described, for example, in DE 10 2017 220 586 A1.

The individual first facets 21 are imaged into the object field 5 with the aid of the second facet mirror 22. The second facet mirror 22 is the last beam-shaping mirror or indeed the last mirror for the illumination radiation 16 in the beam path upstream of the object field 5.

In a further embodiment (not shown) of the illumination optical unit 4, a transfer optical unit contributing in particular to the imaging of the first facets 21 into the object field 5 may be arranged in the beam path between the second facet mirror 22 and the object field 5. The transfer optical unit may have exactly one mirror, or alternatively have two or more mirrors, which are arranged one behind the other in the beam path of the illumination optical unit 4. The transfer optical unit may in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20, and the pupil facet mirror 22.

The deflection mirror 19 can also be dispensed with in a further embodiment of the illumination optical unit 4, and so the illumination optical unit 4 can then have exactly two mirrors downstream of the collector 17, specifically the first facet mirror 20 and the second facet mirror 22.

The imaging of the first facets 21 into the object plane 6 by means of the second facets 23 or using the second facets 23 and a transfer optical unit is, as a rule, only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The penultimate mirror M5 and the last mirror M6 each have a passage opening for the illumination radiation 16. The projection optical unit 10 is a double-obscured optical unit. The projection optical unit 10 has an image-side numerical aperture which is greater than 0.5 and which can also be greater than 0.6 and, for example, can be 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, in particular with alternating layers of molybdenum and silicon.

The projection optical unit 10 has a large object-image offset in the y-direction between a y-coordinate of a center of the object field 5 and a y-coordinate of the center of the image field 11. This object-image offset in the y-direction can be of approximately the same magnitude as a z-distance between the object plane 6 and the image plane 12. In particular, the projection optical unit 10 can have an anamorphic embodiment. In particular, it has different imaging scales βx, βy in the x- and y-directions. The two imaging scales βx, βy of the projection optical unit 10 are preferably (βx, βy)=(+/−0.25, +/−0.125). A positive imaging scale β means imaging without image inversion. A negative sign for the imaging scale β means imaging with image inversion.

The projection optical unit 10 consequently leads to a reduction in size with a ratio of 4:1 in the x-direction, that is to say in a direction perpendicular to the scanning direction.

The projection optical unit 10 leads to a reduction in size of 8:1 in the y-direction, that is to say in the scanning direction.

Other imaging scales are likewise possible. Imaging scales with the same sign and the same absolute value in the x-direction and y-direction are also possible, for example with absolute values of 0.125 or of 0.25.

The number of intermediate image planes in the x-direction and in the y-direction in the beam path between the object field 5 and the image field 11 can be the same or can differ depending on the embodiment of the projection optical unit 10. Examples of projection optical units with different numbers of such intermediate images in the x- and y-directions are known from US 2018/0074303 A1.

In each case one of the pupil facets 23 is assigned to exactly one of the field facets 21 for forming in each case an illumination channel for illuminating the object field 5. In particular, this can yield illumination according to the Köhler principle. The far field is decomposed into a multiplicity of object fields 5 with the aid of the field facets 21. The field facets 21 produce a plurality of images of the intermediate focus on the pupil facets 23 respectively assigned thereto.

By way of an assigned pupil facet 23, the field facets 21 are imaged in each case onto the reticle 7 in a manner superposed on one another for the purposes of illuminating the object field 5. The illumination of the object field 5 is in particular as homogeneous as possible. It preferably has a uniformity error of less than 2%. The field uniformity can be achieved by overlaying different illumination channels.

The illumination of the entrance pupil of the projection optical unit 10 can be defined geometrically by way of an arrangement of the pupil facets. The intensity distribution in the entrance pupil of the projection optical unit 10 can be set by selecting the illumination channels, in particular the subset of the pupil facets which guide light. This intensity distribution is also referred to as illumination setting.

A likewise preferred pupil uniformity in the region of sections of an illumination pupil of the illumination optical unit 4 that are illuminated in a defined manner can be achieved by a redistribution of the illumination channels.

Further aspects and details of the illumination of the object field 5 and in particular of the entrance pupil of the projection optical unit 10 are described below.

The projection optical unit 10 may have in particular a homocentric entrance pupil. The latter can be accessible. It can also be inaccessible.

The entrance pupil of the projection optical unit 10 cannot, as a rule, be exactly illuminated using the pupil facet mirror 22. In the case of imaging of the projection optical unit 10 which telecentrically images the center of the pupil facet mirror 22 onto the wafer 13, the aperture rays often do not intersect at a single point. However, it is possible to find an area in which the spacing of the aperture rays that is determined in pairs becomes minimal. This area represents the entrance pupil or an area in real space that is conjugate thereto. In particular, this area has a finite curvature.

It may be the case that the projection optical unit 10 has different poses of the entrance pupil for the tangential beam path and for the sagittal beam path. In this case, an imaging element, in particular an optical component part of the transfer optical unit, should be provided between the second facet mirror 22 and the reticle 7. With the aid of this optical element, the different poses of the tangential entrance pupil and the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is arranged so as to be tilted with respect to the object plane 6. The first facet mirror 20 is arranged so as to be tilted with respect to an arrangement plane defined by the deflection mirror 19.

The first facet mirror 20 is arranged so as to be tilted with respect to an arrangement plane defined by the second facet mirror 22.

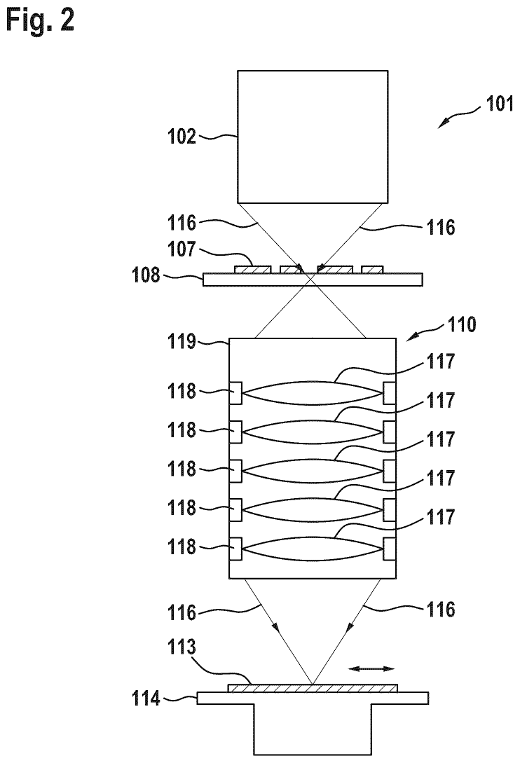

FIG. 2 schematically shows a meridional section of a further projection exposure apparatus 101 for DUV projection lithography, in which the alignment device can likewise be used.

The construction of the projection exposure apparatus 101 and the principle of the imaging are comparable with the construction and procedure described in FIG. 1.

Identical component parts are designated by a reference sign increased by 100 relative to FIG. 1, that is to say the reference signs in FIG. 2 begin with 101.

In contrast to an EUV projection exposure apparatus 1 as described in FIG. 1, refractive, diffractive and/or reflective optical elements 117, such as for example lens elements, mirrors, prisms, terminating plates, and the like, can be used for imaging or for illumination in the DUV projection exposure apparatus 101 on account of the greater wavelength of the DUV radiation 116, employed as used light, in the range from 100 nm to 300 nm, in particular of 193 nm. The projection exposure apparatus 101 in this case essentially comprises an illumination system 102, a reticle holder 108 for receiving and exactly positioning a reticle 107 provided with a structure, by which the later structures on a wafer 113 are determined, a wafer holder 114 for holding, moving, and exactly positioning said wafer 113, and a projection lens 110, with a plurality of optical elements 117, which are held by way of mounts 118 in a lens housing 119 of the projection lens 110.

The illumination system 102 provides DUV radiation 116 required for the imaging of the reticle 107 on the wafer 113. A laser, a plasma source or the like can be used as the source of this radiation 116. The radiation 116 is shaped in the illumination system 102 by means of optical elements such that the DUV radiation 116 has the desired properties with regard to diameter, polarization, shape of the wavefront and the like when it is incident on the reticle 107.

Apart from the additional use of refractive optical elements 117, such as lens elements, prisms, terminating plates, the construction of the downstream projection optical unit 110 with the lens housing 119 does not differ in principle from the construction described in FIG. 1 and is therefore not described in further detail.

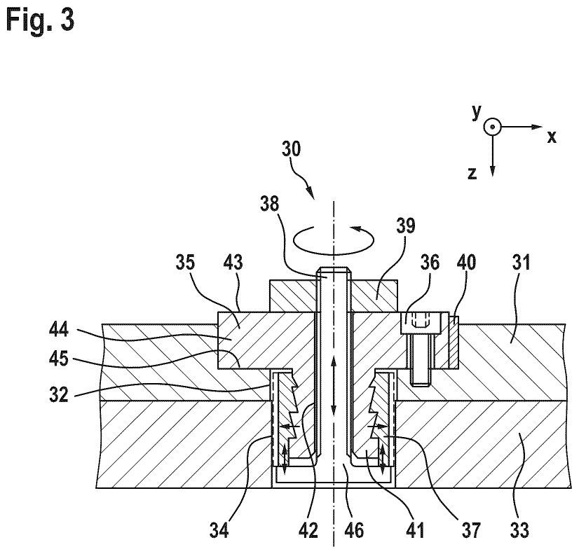

FIG. 3 shows a schematic illustration of a first embodiment of an alignment device with a threaded mandrel 30. The latter aligns a first component embodied as an optical module 31, which comprises for example a mirror Mx, 117 explained in FIG. 1 or FIG. 2, with a second component embodied as a frame 33. The threaded mandrel 30, or simply mandrel 30, has a main body 35 which is positioned via spacers 40 in the optical module 31 with respect to a reference (not shown) in the XY plane defined by the coordinate system drawn in FIG. 3. The main body 35 rests with a flange 44 on a shoulder 45 of a recess 32 formed in the module 31. In order to prevent the main body 35 from twisting when the module 31 is aligned, the main body 35 is connected to the module 31 with a plurality of screws 36, some of which are not visible in section. Following the flange 44 in the direction of the frame 33, a plurality of cones 41 are formed one behind the other at the circumference of the rotationally symmetric main body 35. The main body 35 plunges with the cones 41 through the recess 32 of the module 31 into a recess 34 penetrating the frame 33. The main body 35 further has a through hole 42 through which a clamping screw 38 is guided, which is held on the upper side 43 of the main body 35 with a clamping nut 39. The main body 35 is surrounded in the region of the cones 41 by a clamping sleeve 37 with an internal geometry corresponding to the cones 41. The head 46 of the clamping screw 38 pulls the clamping sleeve 37 onto the cones 41, as shown by the arrows in FIG. 3, so that the clamping sleeve 37 is expanded radially. The radial expansion of the clamping sleeve 37 reduces the clearance between the module 31 and the frame 33, and the two components 31, 33 are aligned with one another. The braced state of the mandrel 30 and thus the reduced clearance between the components 31, 33 is illustrated by dashed lines in FIG. 3. The mandrel 30 therefore has the advantage that when the components 31, 33 are first joined, there is a relatively large clearance between the clamping sleeve 37 and the recess 34 in the frame 33 due to the released state of the clamping sleeve 37. Galling or canting of the two components 31, 33 during joining is thereby advantageously avoided. If the mandrel 30 is then braced, the module 31 is centered in the recess 34 of the frame 33 due to the decreasing clearance. This achieves greater accuracy when aligning the two components 31, 33 than would be possible with a bolt and a drilled hole. This can lead to a relative movement between the components 31, 33. The module 31 is then connected to the frame 33 at points (not shown), and the clamping screw 38 is loosened again to avoid or release tension.

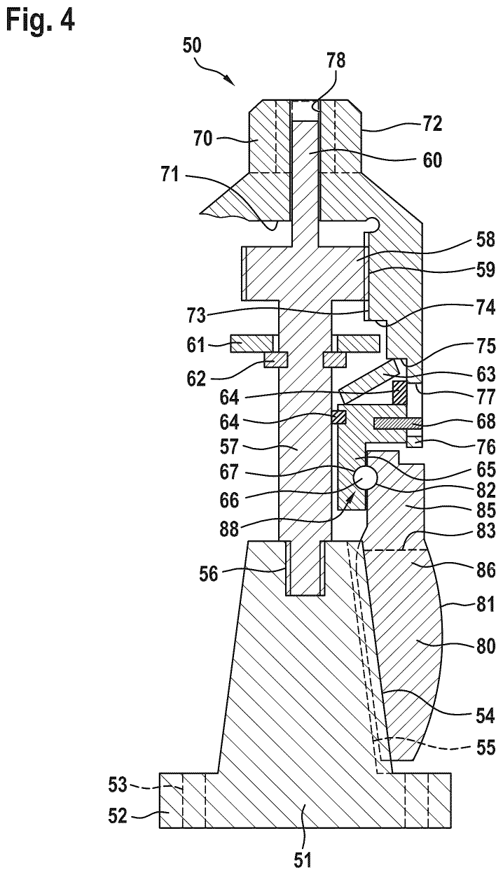

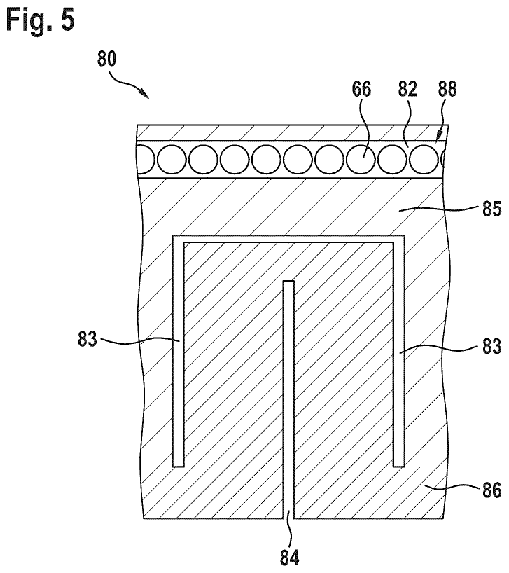

FIG. 4 shows a further embodiment of a threaded mandrel 50 which is suitable in particular for connecting components in a vacuum environment. The threaded mandrel 50, hereinafter referred to as mandrel 50, comprises a main body 51 with a circumferential flange 52 with through holes 53 for connecting the main body 51 to a first component (not shown). Following the flange 52, a cone 54 is formed on the main body 51, the surface of which cone in the embodiment shown in FIG. 4 comprises three grooves 55 offset by 120°. On the side of the main body 51 opposite the flange 52, a shaft 57 is connected to the main body 51 via a thread 56. The shaft 57 is arranged concentrically to the cone 54 and has a thickening 58 with an external thread 59 in the upper region facing away from the main body 51. After the thickening 58, the shaft 57 tapers to form a region embodied in the form of a control pin 60. The control pin 60 plunges into a drilled through hole 78 of a sleeve 70, wherein the length of the control pin 60 is embodied such that when the mandrel 50 is braced to a predetermined extent, the surface of the sleeve 70 and the surface of the region of the shaft 57 embodied as control pin 60 form one plane. This state is illustrated by a displacement of the control pin 60 shown in dashed lines. The upper part of the sleeve 70 comprises an external hexagon 72 for bracing the mandrel 50. In a recess 71 of the sleeve 70, in the region of the thickening 58 of the shaft 57, an internal thread 73 is formed with which the sleeve 70 is screwed onto the shaft 57. The recess 71 has a first shoulder 74 and a second shoulder 75 in the direction of the main body 51. The first shoulder 74 serves as a limit for the bracing of the mandrel 50, i.e., as a stop for the sleeve 70. When the sleeve 70 is being screwed on, after a predetermined distance, the shoulder 74 comes into contact with a shim 61, which is fixed to the shaft 57 via a snap ring 62 and which prevents the sleeve 70 from being screwed further onto the shaft 57. The travel path that is available can be set via the thickness of the shim 61, which is slotted so that it can be slid onto the shaft 57 that has already been installed. As an alternative to the snap ring 62, a further shoulder can also be formed in the shaft 57 as a support for the shim 61. The second shoulder 75 of the sleeve 70 presses on one end of a plate spring 63, which is supported on an intermediate piece 65 with its other end. The plate spring 63 acts in this case as a translation of the travel into a force and thus away from a path control to a force control of the mandrel 50. The stiffness of the plate spring 63 and the travel path can be used to set the force. Alternatively, the shoulder 75 may be reworked or a further shim (not shown) inserted between the shoulder 75 and the plate spring 63 to preload the plate spring 63 to a predetermined force. The plate spring 63 is not absolutely necessary, since the principle also works as a pure path control. The intermediate piece 65 comprises a first half 67 of a circumferential ball bearing 88, wherein the second half 82 of the ball bearing 88 is formed in a rigid and circumferential partial region 85 of a clamping sleeve 80 of the mandrel 50. The balls 66 running in the ball bearing 88 comprise, for example, a ceramic material which is characterized by a high hardness and low particle generation. The balls 66 transmit the force transmitted by the plate spring 63 by screwing-on the sleeve 70 in the axial direction, i.e., in the direction of the longitudinal axis of the mandrel 50, to the clamping sleeve 80. The twisting of the sleeve 70, the plate spring 63, and the intermediate piece 65 is not transmitted to the clamping sleeve 80, as a result of which the particle generation caused by the friction between the clamping sleeve 80 and the cone 54 of the main body 51 is greatly reduced. To further minimize the friction between the clamping sleeve 80 and the cone 54, the clamping sleeve 80 is coated with a ceramic coating (not shown) on its inner side facing the cone 54. The clamping sleeve 80 is pressed in the axial direction onto the cone 54 and expands radially in the process, which, as already explained above in FIG. 3, leads to a reduction in clearance between the mandrel 50 and the drilled hole (not shown) and thus to a more accurate alignment of the two components. The outer contour 81 of the cone 54 is embodied spherically in order to obtain the smallest possible contact surface when the second component (not shown) is first joined onto the mandrel 50, which is connected to a first component. Alternatively, the cone 54 can also have a linear outer contour. The ball bearing 88, which, as already explained above, is formed in part 82 in a partial region 85 of the clamping sleeve 80, must not be expanded radially during bracing. In order to nevertheless enable the expansion of the clamping sleeve 80 during clamping, the first, stiff partial region 85 is decoupled from the second, elastic partial region 86 of the clamping sleeve 80 by decoupling cuts 83, 84 (only part of the decoupling cut 83 is visible in FIG. 4). The position and function of the decoupling cuts 83, 84 are explained in detail in FIG. 5. A portion of the stiff partial region 85 runs, as shown in FIG. 4 by dashed lines, over the entire height of the clamping sleeve 80 and plunges into the grooves 55 of the main body 51 already explained above to avoid radial expansion. The intermediate piece 65 radially has a pin 68 which plunges into a slot 77 in a flank 76 of the sleeve 70. The pin 68 ensures that the intermediate piece 65 rotates with the sleeve 70 and, in addition, it serves to pull the clamping sleeve 80 off the cone 54 of the main body 51 when the mandrel 50 is being released. The pin 68 is positioned in the slot 77 in such a way that it does not transmit any axial forces from the sleeve 70 to the intermediate piece 65 when it is screwed in. By contrast, when the sleeve 70 is unscrewed, the pin 68 comes into contact with the lower periphery of the slot 77, and the clamping sleeve 80 is pulled off the cone 54 via the intermediate piece 65 and the balls 66. The particles generated by the thread 73 arranged in the recess 71 of the sleeve 70 are trapped by the thread 73 and by the seals 64 arranged between the intermediate piece 65 and the shaft 57 or between the intermediate piece 65 and the flank 76 of the sleeve 70 and cannot pass into the environment. This is advantageous in particular for use in a vacuum and for areas with increased requirements relating to freedom from particles, such as clean rooms or vacuum applications. Furthermore, covering the clamping sleeve 80 and the gap between the clamping sleeve 80 and the main body 51 can also catch the particles that are generated on the contact surface of the clamping sleeve 80 and the cone 54 despite the coating of the clamping sleeve 80 explained above.

FIG. 5 shows a detailed view of the inside of a developed clamping sleeve 80. One half 82 of the ball bearing 88 with the balls 66 is arranged in the upper, stiff partial region 85 of the clamping sleeve 80, which in some regions extends almost over the entire height of the clamping sleeve 80. To provide a better understanding, the stiff partial region 85 is shown in FIG. 5 with a different hatching than the elastic partial region 86, although the clamping sleeve 80 is formed in one piece, i.e., monolithically. A first U-shaped decoupling cut 83 allows the upper portion of the elastic partial region 86 to expand radially, while a second decoupling cut 84 allows radial expansion in the lower portion of the elastic partial region 86. This advantageously ensures that the clamping sleeve 80 rests evenly on the cone 54 of the main body 51 and that radial expansion in the region of the ball bearing 88 is avoided.

The mandrel 50 explained in detail in FIG. 4 and FIG. 5 already constitutes an embodiment in itself and should be understood as an independent invention even without its use in a projection exposure apparatus for semiconductor lithography.

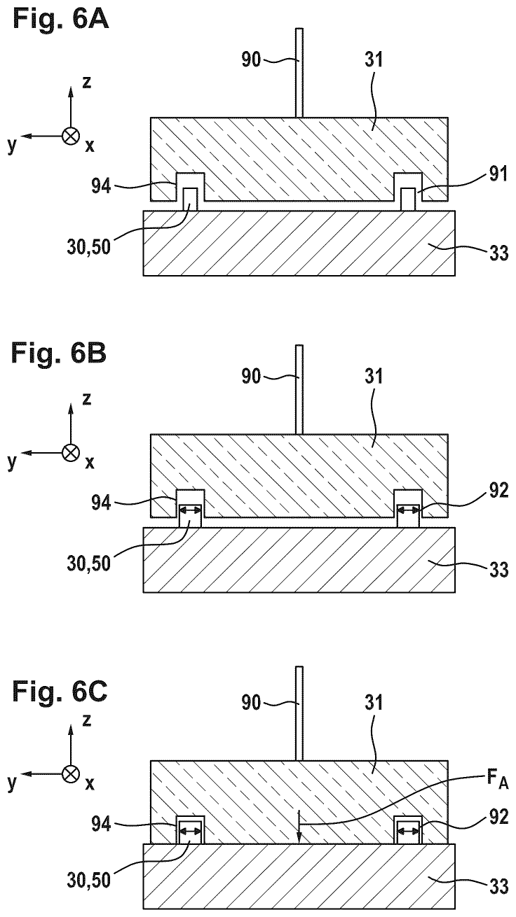

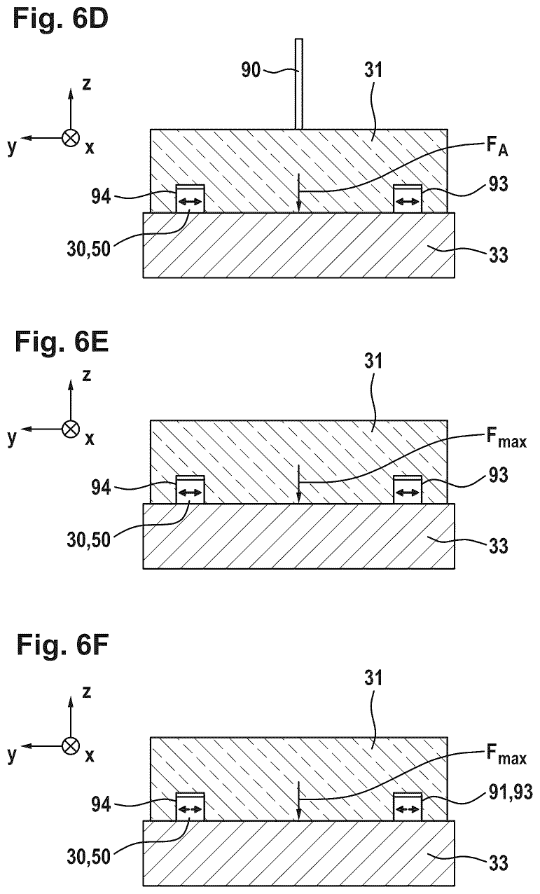

FIGS. 6A to 6F show intermediate steps of a possible method for connecting an optical module 31 and a frame 33 using a mandrel 30, 50 explained in detail in FIG. 3, FIG. 4 and FIG. 5.

FIG. 6A shows a frame 33 with two mandrels 30, 50, wherein the latter are shown in a released operating state 91, which enables a first rough alignment of the optical module 31 with respect to the frame 33. The optical module 31 is connected to a lifting device (not shown) via a connection 90 and hovers in the z-direction in FIG. 6A over the frame 33 such that the mandrel 30, 50 is already plunged into the recess 94 of the optical module 31. In this case, a gap remains in the z-direction between the optical module 31 and the frame 33 in the z-direction, as a result of which an advantageous friction-free pre-positioning between the optical module 31 and the frame 33 is possible. The mandrels 30, 50 pre-position the optical module 31 in relation to the frame 33 in this method step.

FIG. 6B shows a second method step, in which the mandrels 30, 50 are shown in a second operating state 92. In this operating state 92, the mandrels 30, 50 are preloaded with a predetermined torque, so that they rest against the inside of the recess 94 of the optical module 31. The resting is comparable to what is known as a clearance fit, in which minimal clearance is ensured and thus a relative movement in the z-direction between the optical module 31 and the mandrel 30, 50 is possible without the risk of wedging and with minimal friction.

FIG. 6C shows a third method step, in which the optical module 31 is shown in contact with the frame 33. The optical module 31 is lowered in the z-direction only until the contact force F_{A} formed between the optical component 31 and the frame 33 lies in a range of 50 N-150 N, in particular 100 N. The optical module 31 is therefore still connected to the lifting tool via the connection 90. The mandrels 30, 50 continue to be in the operating state 92.

FIG. 6D shows a further method step, in which the mandrels 30, 50 are shown in an operating state 93 in which they are maximally braced in the recesses 94 in the optical module 31. The maximum bracing of the mandrels 30, 50 effects fine positioning between the optical module 31 and the frame 33, wherein the low contact force F_{A} that was set in the prior method step enables a relative movement between the optical module 31 and the frame 33 in the xy plane with a low level of force. The low level of force also reduces the risk of particles being generated between the optical module 31 and the frame 33 as a result of the displacement.

FIG. 6E shows a further method step, in which the optical module 31 is shown without a connection 90 to the lifting tool. The optical module 31 rests with its full weight and the resulting maximum contact force Fₘₐₓ on the frame 33. The mandrels 30, 50 are still in the maximally braced operating state 93.

FIG. 6F shows a final method step, in which the mandrels 30, 50 are first brought into the released operating state 91 explained in FIG. 6A and then back into the maximally braced operating state 93, which has already been explained in FIG. 6D and FIG. 6E.

This is indicated in FIG. 6F by the dashed double-headed arrow within the mandrels 30, 50. As a result, possible tension frozen in the optical module 31 when the optical module 31 is fully lowered is relaxed. Due to the maximum contact force Fₘₐₓ, a change in the position of the optical module 31 relative to the frame 33 occurring in the process is very unlikely or negligible.

Additional embodiments are within the scope of the following claims.

### LIST OF REFERENCE SIGNS

1 Projection exposure apparatus
2 Illumination system
3 Radiation source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Threaded mandrel
31 Optical module
32 Recess in module
33 Frame
34 Recess in frame
35 Main body
36 Screw
37 Clamping sleeve
38 Clamping screw
39 Clamping nut
40 Spacer
41 Cone
42 Through hole
43 Upper side of main body
44 Flange
45 Shoulder
46 Head of the clamping screw
50 Threaded mandrel
51 Main body
52 Flange
53 Through holes
54 Cone
55 Groove
56 Thread
57 Shaft
58 Thickening
59 External thread
60 Control pin
61 Shim
62 Snap ring
63 Plate spring
64 Seal
65 Intermediate piece
66 Ball
67 Ball bearing half
68 Pin
70 Sleeve
71 Recess
72 Hexagon
73 Internal thread
74 First shoulder
75 Second shoulder
76 Flank
77 Slot
78 Drilled through hole
80 Clamping sleeve
81 Outer contour of clamping sleeve
82 Ball bearing half
83 First release cut
84 Second release cut
85 Stiff partial region
86 Elastic partial region
90 Connection to lifting device
91 Threaded mandrel, released
92 Threaded mandrel, applied (clearance fit)
93 Threaded mandrel, braced (press fit)
94 Recess in optical module
101 Projection exposure apparatus
102 Illumination system
107 Reticle
108 Reticle holder
110 Projection optical unit
113 Wafer
114 Wafer holder
116 DUV radiation
117 Optical element
118 Mounts
119 Lens housing
M1-M6 Mirrors
F_{A} Contact force, optical module
Fₘₐₓ Weight force, optical module

What is claimed is:

1. A method for aligning two components of a projection exposure apparatus for semiconductor lithography, comprising:
inserting at least one mandrel of a first component into a recess of a second component in a z-direction, wherein the at least one mandrel provides a radial expansion of at least a portion of the mandrel perpendicular to the z-direction in response to an axial movement or feed in the mandrel along the z-direction caused by a torque,
preloading the radial expansion of the mandrel to a predetermined torque for pre-positioning the two components in relation to each other in an x-y plane perpendicular to the z-direction,
positioning the two components in the z-direction until they are in contact with a contact force F_{A},
bracing the mandrel with the recess with a radial expansion corresponding to a maximum torque greater than the pre-determined torque,
positioning the two components in the z-direction until the first component rests on the second component with a maximum weight force Fₘₐₓ greater than the contact force F_{A}.

2. The method of claim 1, wherein
the mandrel is braced with a contact force F_{A} of less than 1000 N.

3. The method of claim 1, further comprising:
loosening the at least one mandrel after the two components are positioned with the maximum weight force Fₘₐₓ, and thereafter again bracing the mandrel with the recess with a radial expansion corresponding to a torque greater than the pre-determined torque.

4. A device for aligning two components of a projection exposure apparatus for semiconductor lithography, comprising:
a mandrel that provides a radial expansion of at least a portion of the mandrel perpendicular to the z-direction in response to an axial movement or feed in the mandrel along the z-direction caused by a torque.

5. The device of claim 4, further comprising a first one of the two components, and wherein the mandrel is permanently connected to the first component.

6. The device of claim 5, further comprising a second one of the two components, and wherein the second component has a recess corresponding to an outer diameter of the mandrel.

7. The device of claim 6, wherein the mandrel is embodied in such a way that it can switch between a released state and a braced state in response to the torque.

8. The device of claim 7, wherein a joint clearance between the recess and the mandrel in the released state is greater than or equal to 30 μm.

9. The device as claimed in claim 7, wherein a joint clearance between the recess and the mandrel in the braced state is less than 30 μm.

10. The device of claim 6, wherein the mandrel comprising a clamping element is connected to a clamping sleeve or a main body in such a way that only axial forces are transmitted to the mandrel portion having the radial expansion.

11. The device of claim 10, wherein the clamping sleeve and/or the main body is coated with a friction-reducing layer.

12. The device of claim 10, wherein an outer contour of the clamping sleeve or an inner contour of the corresponding recess has a rounded geometry.

13. The device of claim 6, further comprising a weight compensation unit for one of the components.

14. The device of claim 6, further comprising an indicator for indicating a successful alignment.

15. The device of claim 6, wherein the mandrel has a predetermined maximum travel along the z-direction.

16. The device of claim 15, wherein the predetermined maximum travel is settable.

17. The device of claim 4, wherein the mandrel has a circumferential ball bearing.

18. The device of claim 10, wherein the clamping sleeve has a stiff partial region and an elastic partial region.

19. The device of claim 10, wherein the clamping sleeve has a monolithic structure.

20. The device of claim 15, wherein the mandrel has an internal thread for effecting the travel.

21. The device of claim 10, wherein the mandrel has a volume surrounding the thread that is sealed off from the outside by at least one seal to avoid particle contamination.

22. The method of claim 2, wherein the mandrel is braced with a contact force F_{A} of less than 100 N.

23. The method of claim 2, wherein the mandrel is braced with a contact force F_{A} of less than 10 N.

24. The device of claim 9, wherein the joint clearance between the recess and the mandrel in the braced state is less than 15 μm.

25. The device of claim 9, wherein the joint clearance between the recess and the mandrel in the braced state is less than 5 μm.
